(19) United States
(12) Patent Application Publication
(10) Pub. No.: US 2025/0167074 A1
(43) Pub. Date: May 22, 2025

(54) PASSIVE THERMAL CONTROL LAYER FOR INTEGRATED DEVICE

(71) Applicant: Taiwan Semiconductor Manufacturing Company, Ltd., Hsinchu (TW)

(72) Inventors: Sam Vaziri, San Jose, CA (US); Isha Datye, Hsinchu (TW); Xinyu Bao, Fremont, CA (US)

(21) Appl. No.: 18/582,781

(22) Filed: Feb. 21, 2024

Related U.S. Application Data
(60) Provisional application No. 63/600,060, filed on Nov. 17, 2023.

(51) Int. Cl. H01L 23/427; H01L 21/768; H01L 23/367; H01L 23/528

(52) U.S. Cl. CPC H01L 23/427; H01L 21/76895; H01L 23/367; H01L 23/5283

(57) ABSTRACT

Some embodiments relate to an integrated device, including a substrate having at least one active component; an interconnect structure disposed on the substrate; a bonding layer disposed over the interconnect structure; a carrier substrate disposed over the bonding structure; a heat dissipating module disposed over the carrier substrate; and a first thermal control layer disposed between the carrier substrate and the heat dissipating module, the bonding layer and the interconnect structure, or the carrier substrate and the bonding layer, wherein the first thermal control layer comprises a phase change material (PCM).

### REFERENCE TO RELATED APPLICATION

This Application claims priority to U.S. Provisional Application No. 63/600,060, filed on Nov. 17, 2023, the contents of which are hereby incorporated by reference in their entirety.

### BACKGROUND

Circuit components within integrated devices generate heat during operation. The heat generated may damage the components, leading to a loss of efficiency or potentially failure of the integrated device. A variety of methods of dispersing or transferring the heat away from the circuit components have been developed, including using materials with a higher thermal conductivity than silicon dioxide and forming vias that extend through the device and conduct heat towards the outer sidewalls of a semiconductor package.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of an integrated device with one or more thermal control layers disposed between an interconnect structure and an upper surface of the semiconductor package.

FIG. 2 illustrates an exemplary graph of the temperature change of a thermal control layer during phase transition.

FIG. 3 illustrates a cross-sectional view of some embodiments of an integrated device with one or more thermal control layers disposed between the interconnect structure and an outer sidewall of the semiconductor package, further comprising a heat spreader within the interconnect structure.

FIG. 4 illustrates a cross-sectional view of some embodiments of an integrated device with one or more thermal control layers, where the thermal control layers are patterned.

FIG. 5 illustrates a cross-sectional view of some embodiments of an integrated device with one or more thermal control layers, where the thermal control layers are coupled to one or more high thermal conductivity layers to increase the transfer of heat through the device.

FIGS. 6A-6B illustrate cross-sectional views of some embodiments of an integrated device with one or more thermal control layers, where the thermal control layers are patterned and coupled to one or more high thermal conductivity layers to increase the transfer of heat through the device.

FIGS. 7-8, 9A, 9B, and 10-13 illustrate a series of cross-sectional views of some embodiments of a method of forming an integrated device with one or more thermal control layers disposed between the interconnect structure and an outer sidewall of the semiconductor package.

FIGS. 14-18 illustrate a series of cross-sectional views of some embodiments of methods of forming one or more patterned thermal control layers disposed between the interconnect structure and an outer sidewall of the semiconductor package.

FIG. 19 illustrates a flowchart of some embodiments of a method of forming one or more patterned thermal control layers disposed between the interconnect structure and an outer sidewall of the semiconductor package.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An integrated device may comprise a semiconductor substrate, a plurality of semiconductor devices, and an interconnect structure overlying the semiconductor devices. The semiconductor devices perform many operations important to the functioning of the integrated device, such as computation and data retention. During the operations, resistance within the plurality of semiconductor devices and other components results in thermal energy building up within the integrated device as heat. The buildup of heat increases the resistance of many materials, and may degrade the efficiency of device operation, leading to a loss of performance and potentially a failure of the integrated device.

In some embodiments, a number of technological developments are incorporated to both reduce the impact of the heat on the functioning of the semiconductor devices and disperse the heat into the ambient environment outside of the integrated device, lowering the damage done. Some of these developments include using materials with a high thermal conductivity to transfer the heat at a higher rate, which reduces the amount of heat that may build up at the semiconductor devices. Further, the use of thermal interface materials (TIMs) and heat dissipating modules also transfer heat away from the semiconductor devices. In some embodiments, the semiconductor devices are modified to distribute the concentration of heat throughout the device or be more resilient to potentially damaging temperatures. Current dynamic solutions to transfer heat away from semiconductor devices include using microchannels and liquid cooling. However, these solutions are complicated and costly.

The aforementioned developments may be used to improve the heat management within an integrated circuit, but in some embodiments integrated circuits are dormant for extended periods of time which are separated by periods of activity, leading to fast transient temperature spikes. The fast transient temperature spikes may overwhelm the heat transferring abilities of the aforementioned developments, rapidly introducing an amount of thermal energy that may cause damage to the semiconductor devices even with the improved heat transfer rates from TIMs, high thermal conductivity materials and heat dissipating modules. Therefore, a method of reducing the effects of a fast transient increase in temperature on the integrated device is desirable.

The present disclosure provides an integrated device with a thermal control layer. The thermal control layer is a phase-change material (PCM) and has a large heat capacity relative to other thermally conductive materials and additionally absorbs thermal energy as latent heat (e.g., energy that causes a transition between phases rather than a change in temperature) around a phase transition temperature of the material. The increase in heat capacity and energy absorption results in the thermal control layer absorbing thermal energy and reducing the overall temperature increase caused by the fast transient spikes. The absorbed thermal energy is then released during the extended periods of dormancy, and is released at a slower rate than the thermal energy was absorbed. The slower release of the thermal energy at a slower rate is dispersed by the TIM and the heat dissipation modules. Therefore, the introduction of a thermal control layer effectively reduces the increase in temperature within the integrated device during fast transient spikes, resulting in the semiconductor devices having a longer lifetime and reduced risk of failure during operation. The thermal characteristics of the thermal control layer may be modified by tuning the composition and doping of the layer, resulting in a variety of phase transition temperatures and hysteresis curves being available from introducing one passive component.

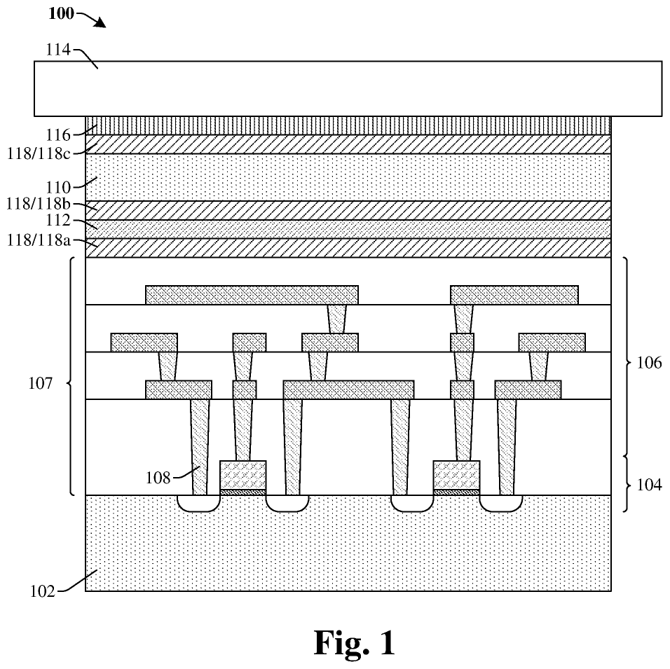

FIG. 1 illustrates a cross-sectional view 100 of some embodiments of an integrated device with one or more thermal control layers disposed between an interconnect structure and an upper surface of the semiconductor package.

As shown in the cross-sectional view 100 of FIG. 1, a plurality of semiconductor devices 104 are disposed over a substrate 102. In some embodiments, the plurality of semiconductor devices 104 may comprise transistor devices (e.g., planar FETs, FinFETs, gate-all-around (GAA) devices, etc.). The plurality of semiconductor devices 104 are coupled to an interconnect structure 106 by a plurality of contacts 108. The interconnect structure 106 couples the plurality of semiconductor devices 104 to one another and/or to a plurality of back-end-of-line (BEOL) devices (not shown). The interconnect structure 106 and the plurality of semiconductor devices 104 are surrounded by an interlayer dielectric 107.

A carrier substrate 110 is coupled to the interconnect structure 106 by a bonding layer 112. The carrier substrate 110 is further coupled to a heat dissipating module 114 by a thermal interface material (TIM) 116. The heat dissipating module 114 is, for example, a thermally conductive casing surrounding the integrated device, or a heat sink coupled to a thermally conductive casing. In some embodiments, the heat dissipating module 114 may comprise a heat sink that includes a plurality of fins protruding outward from a horizontally extending surface away from the carrier substrate 110.

One or more thermal control layers 118 are arranged over the interconnect structure 106. In some embodiments, the one or more thermal control layers 118 may line surfaces of the carrier substrate 110 or the bonding layer 112. In some embodiments, the thermal control layers 118 are or comprise a shape memory alloy (SMA) material, a solid-solid phase change (S-S PCM) material, or the like. In various embodiments, the one or more thermal control layers 118 may comprise one or more of a first thermal control layer 118a disposed between the bonding layer 112 and the interconnect structure 106, second thermal control layer 118b disposed between the carrier substrate 110 and the bonding layer 112, and a third thermal control layer 118c disposed between the carrier substrate 110 and the heat dissipating module 114.

The positioning of the one or more thermal control layers 118 within the semiconductor packaging results in a reduction in the peak temperature during a fast transient temperature spike. The material of the thermal control layers 118 is chosen to have a phase transition region within a temperature band in which the integrated circuit can safely operate. When the temperature of the thermal control layers 118 is within the phase transition region, the thermal control layers 118 absorb thermal energy as latent heat. Because latent heat is energy that causes a transition between different phases, the absorption of thermal energy does not increase temperature and therefore reduces the rate of temperature increase within the integrated device and the peak temperature reached. By reducing the peak temperature, the internal resistance at the peak temperature reached is lower. The lower internal resistance increases the efficiency of the integrated circuit and reduces the resulting degradation (e.g., degradation of performance) of the plurality of semiconductor devices 104, increasing the lifetime of the integrated device.

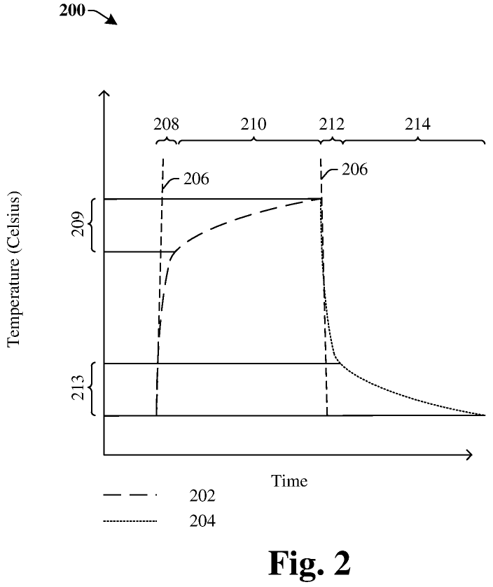

FIG. 2 illustrates an exemplary graph 200 of the temperature change of a thermal control layer during phase transition.

The graph 200 shows the temperature change of the thermal control layers (see 118 of FIG. 1) over time during both a heating phase 202 (e.g., the fast transient temperature spikes) and a cooling phase 204 (e.g., the extended periods of dormancy). During a first portion 208 of the heating phase 202, the material of the thermal control layers (see 118 of FIG. 1) is primarily in a first phase, and the temperature change in a thermal control layer is approximately the same as the temperature change in a material without a phase change 206. During a second portion 210 of the heating phase 202, the temperature is within the first phase change region 209, and the material begins to transition from a first phase to a second phase. The transition from the first phase to the second phase absorbs heat that is added throughout the fast transient temperature spike, reducing the total increase in temperature compared to the temperature change in a material without a phase change 206.

In the cooling phase, the material of the thermal control layers (see 118 of FIG. 1) is primarily in a second phase. In some embodiments, the second phase change region 213 is a same temperature or temperature range as the first phase change region 209. In other embodiments, the second phase change region 213 is at or centered on a lower temperature than the first phase change region 209. During a first portion 212 of the cooling phase 204, the temperature decreases at a rate comparable to a temperature change in a material without a phase change 206 and similar specific heat capacity. During a second portion 214 of the cooling phase 204, the temperature is within the second phase change region 213, and the material begins to transition from the second phase to the first phase. The transition from the second phase to the first phase releases heat that was absorbed during the fast transient temperature spike, and reduces the rate of decrease in temperature compared to the temperature change in a material without a phase change 206. That is, the transition from the second phase to the first phase and the resulting release of heat is a gradual process that takes a longer period of time than a similar change in temperature in a material without a phase change 206 would take. The release of heat occurs at a temperature that the semiconductor devices can operate at without being damaged, reducing the performance degradation that may occur during the fast transient temperature spikes by reducing the maximum temperature reached.

The difference in the rate of temperature gain at varying temperatures is due to the latent heat used by the material to transition between phases. The latent heat absorbed by the thermal control layers 118 as they transition between a first phase and a second phase does not increase the temperature of the thermal control layers 118, resulting in a reduction in the total temperature increase that may occur during fast transient temperature spikes.

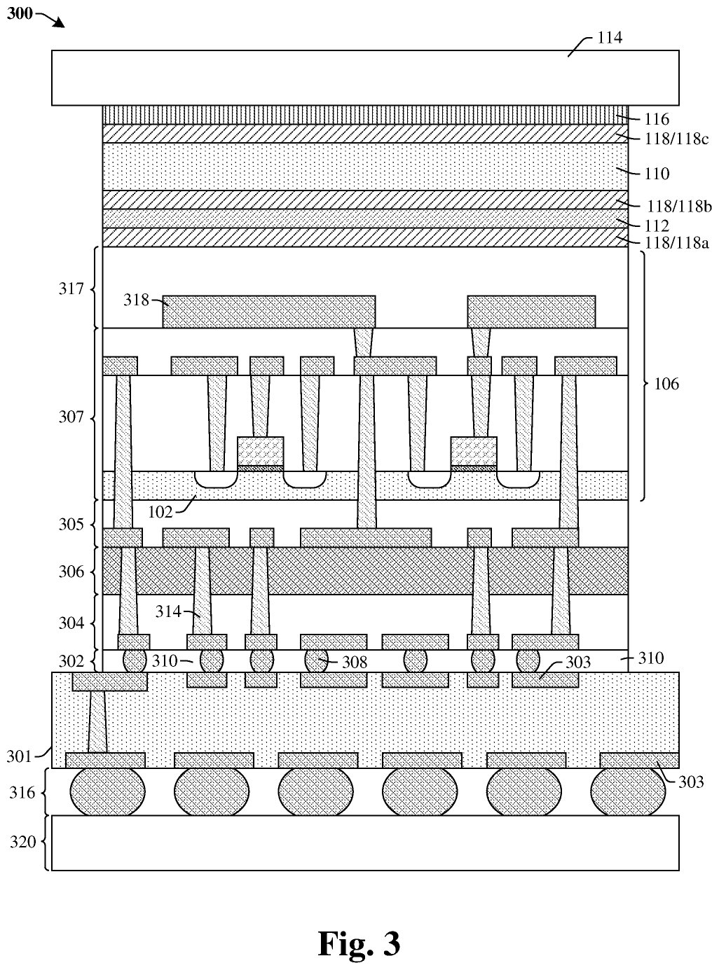

FIG. 3 illustrates a cross-sectional view 300 of some embodiments of an integrated device with one or more thermal control layers disposed between the interconnect structure and an outer sidewall of the semiconductor package, further comprising a heat spreader within the interconnect structure.

In some embodiments, the integrated device comprises a multiple stacked chips. The substrate 102 may be coupled to a multilayer board 320 through a second substrate 301. The second substrate 301 is coupled to the multilayer board 320 using a ball grid array 316. A controlled collapsed chip connection 302 overlies the second substrate 301. The controlled collapsed chip connection 302 couples a second interconnect structure 303 of the second substrate 301 to a bond pad layer 304. The second interconnect structure 303 is coupled to the bond pad layer 304 using a plurality of solder balls 308. The solder balls are spaced by a gap-fill, and form a controlled collapsed chip connection (C4) layer 310.

A heat spreader 306 overlies the bond pad layer 304. The heat spreader 306 comprises a high thermal conductivity material, such as diamond or the like. A back metal layer 305 separates the heat spreader 306 from the substrate 102. The bond pad layer 304 and the back metal layer 305 both comprise a second plurality of wires that are electrically coupled by a second plurality of vias 314 extending through the heat spreader 306.

The substrate 102 and the interconnect structure 106 comprise a plurality of logic layers 307 within the integrated device. The uppermost layer of the interconnect structure 106 is a top metal layer 317. The top metal layer 317 has a wire layer 318 with a greater thickness than the wire layers of the rest of the interconnect structure 106.

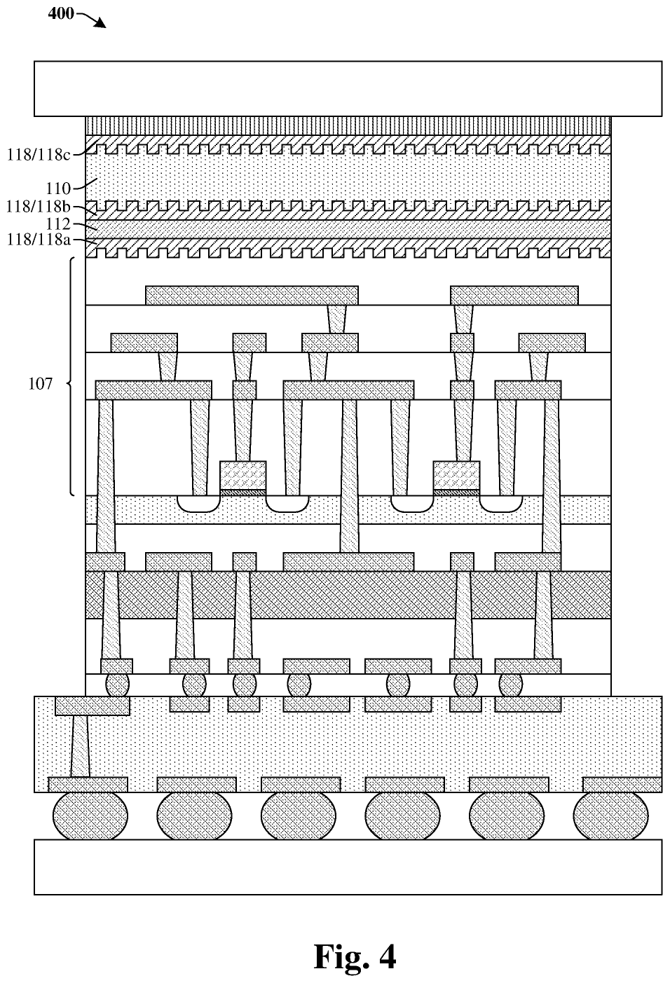

FIG. 4 illustrates a cross-sectional view 400 of some embodiments of an integrated device with one or more thermal control layers, where the thermal control layers are patterned.

In some embodiments, the one or more thermal control layers 118 are comprise a plurality of grooves and protrusions. The plurality of grooves and protrusions increase the surface area of the thermal control layer 118, increasing the rate of heat transfer between the layers coupled to the thermal control layers 118. The plurality of grooves are formed by sidewalls and horizontally extending surfaces of the one or more thermal control layers 118. In some embodiments, the sidewalls of the one or more thermal control layers 118 contact sidewalls of a carrier substrate 110. In some embodiments (not shown), respective ones of the one or more thermal control layers 118 may comprise grooves and protrusions along opposing sides of a thermal control layer (e.g., along a top and a bottom of a thermal control layer).

The plurality of grooves are formed by one of two methods: either a plurality of grooves are etched into an underlying layer (e.g., the interlayer dielectric 107, the bonding layer 112, or the carrier substrate 110), and the thermal control layers 118 are formed within the grooves, or a plurality of grooves are etched into the thermal control layers 118, and overlying layers are formed within the grooves. Either or both of these processes may be used to pattern the thermal control layers 118. For example, in FIG. 4, before the carrier substrate 110 is bonded to the bonding layer 112, the first, second, and third thermal control layers 118a, 118b, 118c are patterned by etching the underlying layer (e.g., the interlayer dielectric 107 below the first thermal control layer 118a and the carrier substrate 110 below the second and third thermal control layers 118b, 118c) and forming the first, second, and third thermal control layers 118a, 118b, 118c over the patterned underlying layers. In some embodiments, a first surface of the carrier substrate 110 is etched and the second thermal control layer 118b is formed within the resulting openings. Subsequently, a second surface of the carrier substrate is etched and the third thermal control layer 118c is formed within the resulting openings. In other embodiments, both the first surface and the second surface are etched prior to the forming of the second thermal control layer 118b and the third thermal control layer 118c.

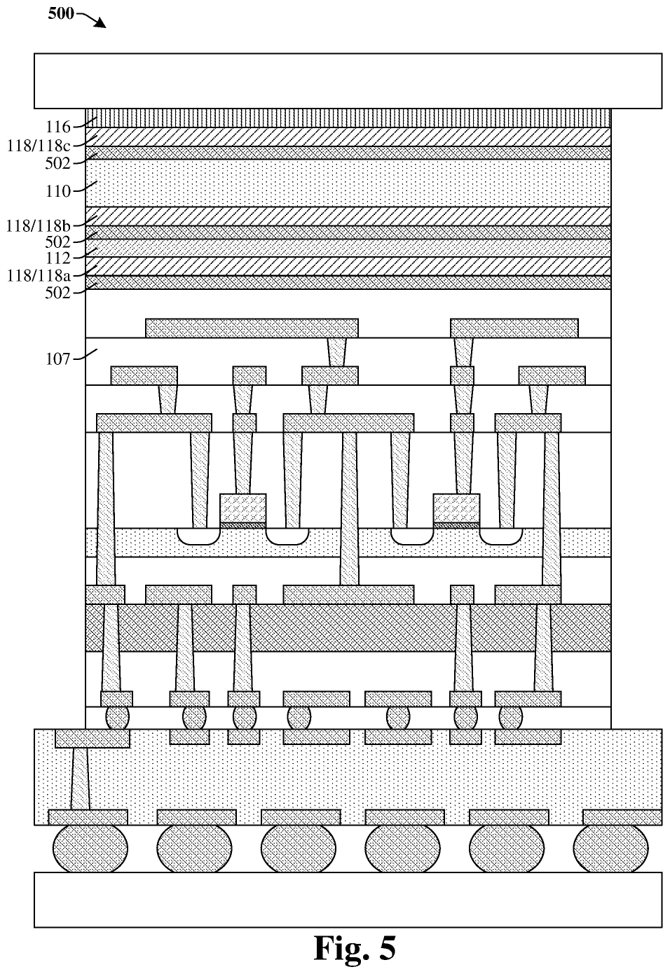

FIG. 5 illustrates a cross-sectional view of some embodiments of an integrated device 500 with one or more thermal control layers, where the thermal control layers are coupled to one or more high thermal conductivity layers to increase the transfer of heat through the device.

In some embodiments, the thermal control layers 118 are coupled to high thermal conductivity layers 502 to increase the transfer of heat through the integrated device. The high thermal conductivity layers 502 comprise a high thermal conductivity material, such as diamond or the like. The presence of the high thermal conductivity layers 502 enhances the heat transfer coefficient of the integrated device near the thermal control layers 118, resulting in a greater responsiveness and increased ability for the thermal control layers 118 to absorb or release heat from the surrounding layers. The high thermal conductivity layers 502 further improve the distribution of heat throughout the device, reducing the amount of heat that stays in areas with a high concentration of heat generated (e.g., near higher-powered devices, etc.). That is, the high thermal conductivity layers 502 redistribute the heat generated, alleviating the buildup of heat at hotspots in the integrated device. The high thermal conductivity layers 502 are disposed between the coupled thermal control layers 118 and the semiconductor devices 104, resulting in heat generated by active components being distributed across the surface of the thermal control layers 118. In some embodiments, the high thermal conductivity layers 502 have thicknesses between approximately 200 nanometers and 5 micrometers, approximately 300 nanometers and 4 micrometers, approximately 100 nanometers and 4.5 micrometers, or the like. In some embodiments, a ratio of thicknesses of the thermal control layers 118 and the thicknesses of the high thermal conductivity layers 502 is between approximately 1-to-1 and approximately 1-to-10.

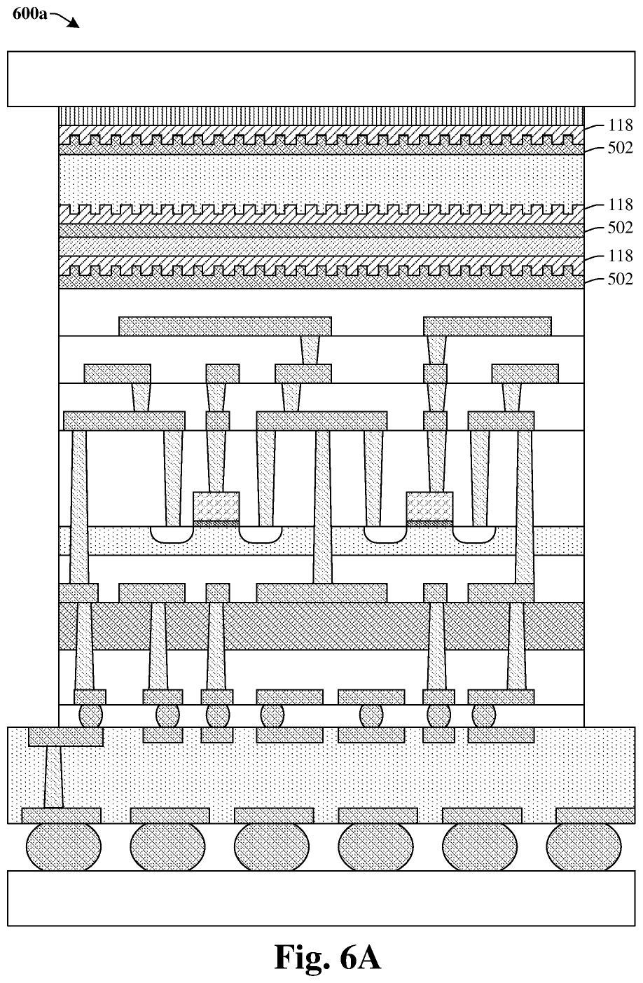

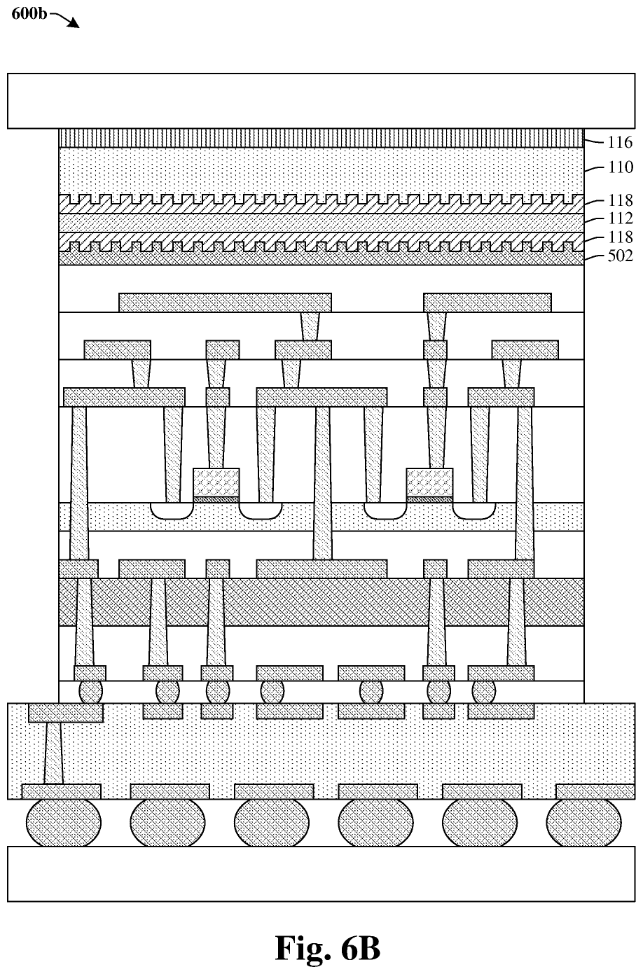

FIGS. 6A-6B illustrate cross-sectional views 600a, 600b of some embodiments of an integrated device with one or more thermal control layers, where the thermal control layers are patterned and coupled to one or more high thermal conductivity layers to increase the transfer of heat through the device.

In some embodiments, the high thermal conductivity layers 502 are utilized with the patterned thermal control layers 118 to further enhance the thermal conductivity of the device and improve the effectiveness of the thermal control layers 118. When the thermal control layers 118 have patterned surfaces contacting the high thermal conductivity layers 502, the increased surface area at the interface further increases the amount of heat the thermal control layers 118 may absorb. In some embodiments, as shown in FIG. 6B, one or more of the high thermal conductivity layers 502 are omitted. That is, in some embodiments, the integrated device may have a greater number of thermal control layers 118 than the number of high thermal conductivity layers 502.

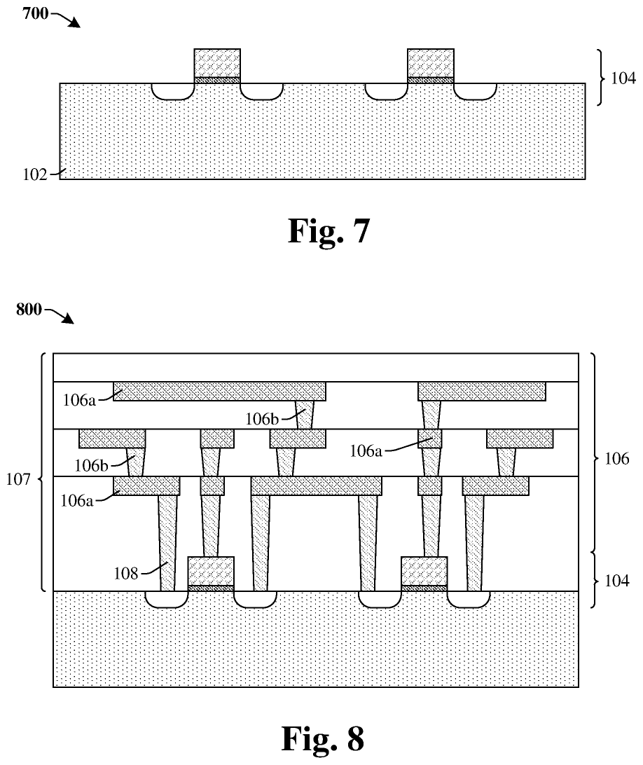

FIGS. 7-8, 9A, 9B, and 10-13 illustrate a series of cross-sectional views 700-1300 of some embodiments of a method of forming an integrated device with one or more thermal control layers disposed between the interconnect structure and an outer sidewall of the semiconductor package. Although FIGS. 7-13 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in the cross-sectional view 700 of FIG. 7, a substrate 102 is provided, and the plurality of semiconductor devices 104 are formed on the provided substrate 102. The substrate 102 may be any suitable type of substrate and/or may, for example, be a semiconductor wafer, one or more dies on a wafer, or any other suitable type of semiconductor body and/or epitaxial layers. In some embodiments, the substrate 102 is or comprises silicon, sapphire, the like, or any combination of the foregoing. In some embodiments, the plurality of semiconductor devices 104 are or comprise one or more layers, including a first gate, a first dielectric, and source/drain regions. The first gate is or comprises a conductive material, such as copper (Cu), titanium (Ti), aluminum (Al), doped polysilicon, the like, or a combination of the foregoing. In some embodiments, the first dielectric is or comprises an insulator, such as silicon dioxide (SiO₂), a high-k dielectric, or the like. The source/drain regions are or comprise regions with a high concentration (e.g., greater than 10¹⁵ atoms/cm³) of dopants, resulting in a high concentration of carriers within the source/drain regions.

As shown in the cross-sectional view 800 of FIG. 8, the interconnect structure 106 is formed over the substrate 102. In some embodiments, the interconnect structure 106 is or comprises a conductive material such as copper (Cu), titanium (Ti), aluminum (Al), the like, or a combination of the foregoing. The interconnect structure comprises a plurality of wire levels 106a and a plurality of via levels 106b. The interconnect structure 106 is formed by depositing a layer of the interlayer dielectric 107, etching a plurality of openings in the interlayer dielectric 107, and filling the openings with the conductive material. The process outlined above repeats until the interconnect structure is completed. In some embodiments, the plurality of contacts 108, the plurality of wire levels 106a, and the plurality of via levels 106b are formed using separate damascene processes. In other embodiments, pairs of wire levels 106a and via levels 106b may be formed concurrently using a plurality of dual-damascene processes. A plurality of contacts 108 are formed in a first layer of the interlayer dielectric 107 before the formation of the wire levels 106a and via levels 106b. The plurality of contacts 108 couple the plurality of semiconductor devices 104 to the interconnect structure 106.

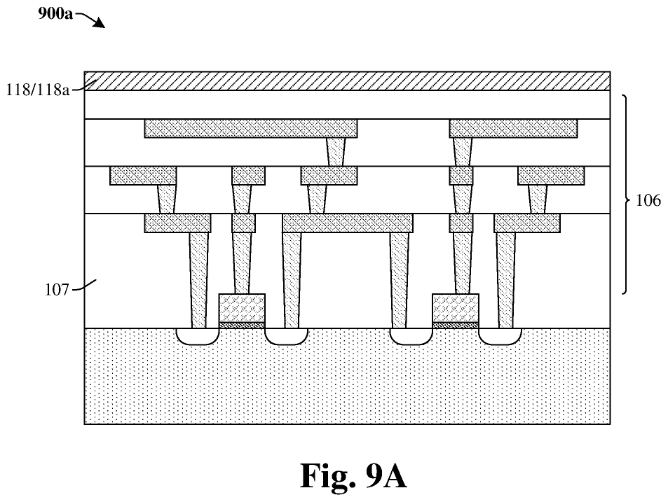

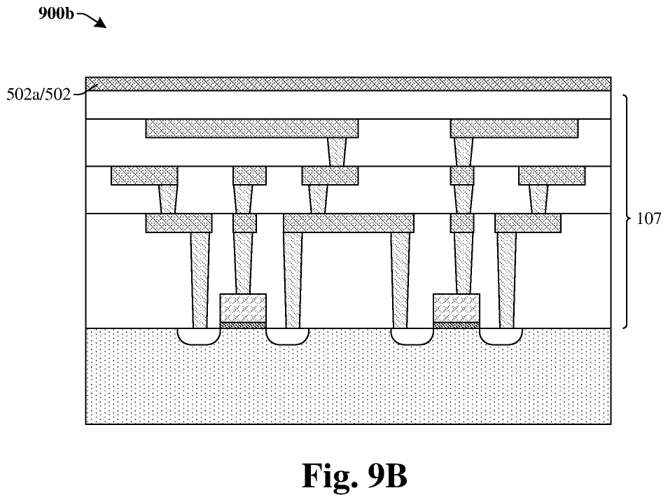

As shown in the cross-sectional view 900a of FIG. 9A, the first thermal control layer 118a is formed on the interlayer dielectric 107 over the interconnect structure 106. In some embodiments, the first thermal control layer is omitted. In some embodiments, the first thermal control layer 118a is or comprises a shape memory alloy, such as nickel titanium alloy (NiTi), nickel titanium hafnium alloy (NiTiHf), nickel copper titanium alloy (NiCuTi), nickel copper titanium hafnium alloy (NiCuTiHf), nickel titanium vanadium alloy (NiTiV), or the like. In other embodiments, the first thermal control layer 118a comprises a solid-solid PCM that is not a shape memory alloy, such as vanadium oxide (VO₂) or the like. In further embodiments, the first thermal control layer 118a may comprise a solid-liquid PCM, such as paraffin or the like. Embodiments utilizing a solid-liquid PCM further comprise microchannels or another method of containing the PCM when it is in a liquid state. In some embodiments, the first thermal control layer 118a may comprise a latent heat that is between approximately 10 Joule/gram (J/g) and approximately 150 J/g, that is between approximately 5 J/g and approximately 145 J/g, or other similar values. In some embodiments, the first thermal control layer 118a is formed using one of ALD, CVD, PVD, or the like. In some embodiments, the first thermal control layer 118a has a first thickness between approximately 0.1 micrometers and 5 micrometers, between approximately 0.5 micrometers and 4 micrometers, between approximately 0.2 micrometers and 4.5 micrometers, or the like.

In some embodiments, as shown in the cross-sectional view 900b of FIG. 9B, a first high thermal conductivity layer 502a of the high thermal conductivity layers 502 is formed on the interlayer dielectric 107 before the first thermal control layer (see 118a of FIG. 9A) is formed. The high thermal conductivity layers 502 comprise a high thermal conductivity material, such as diamond, cubic boron nitride (BN), or the like. In some embodiments, the first high thermal conductivity layer 502a is formed using a microwave plasma-enhanced chemical vapor deposition (MPCVD) process at less than 400 degrees Celsius. In further embodiments, the first high thermal conductivity layer 502a comprises a seed layer that is formed before the MPCVD process. The seed layer may be or comprise diamond nanoparticles, cubic boron nitride (BN) thin films or nano particles, cubic boron phosphide thin films or nanoparticles, or the like. A final portion of the first thermal control layer 118a is formed by applying the MPCVD process to the seed layer. In some embodiments, the first high thermal conductivity layer 502a has a second thickness between approximately 200 nanometers and 5 micrometers, approximately 300 nanometers and 4 micrometers, approximately 100 nanometers and 4.5 micrometers, or the like. In some embodiments, a ratio of the second thickness of the first high thermal conductivity layer 502a and the first thickness of the first thermal control layer (see 118a of FIG. 9A) is between approximately 1-to-1 and approximately 1-to-10.

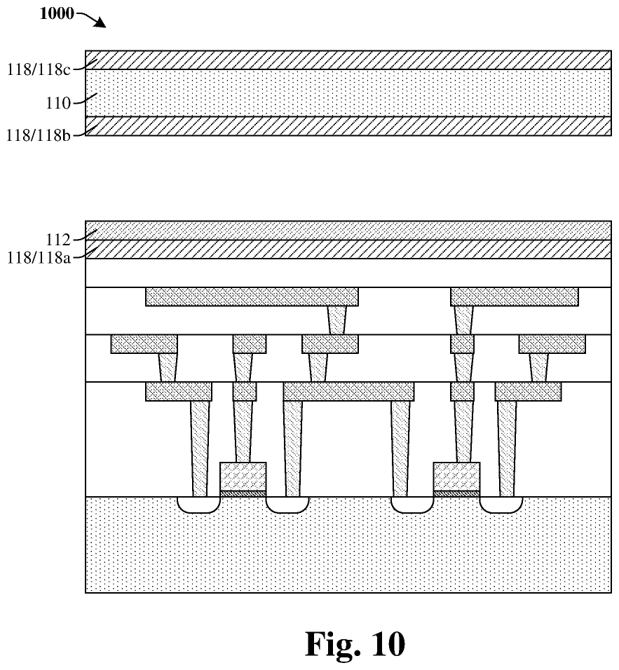

As shown in the cross-sectional view 1000 of FIG. 10, the bonding layer 112 is formed over the first thermal control layer 118a, and the second and third thermal control layers 118b, 118c are formed on the carrier substrate 110. In some embodiments, the bonding layer 112 is formed using a spin-on process, a spray-on process, or the like. In some embodiments, the bonding layer 112 comprises an adhesive bonding material, such as benzocyclobutene (BCB) or the like. The bonding layer 112 has a first stiffness that is lower than a second stiffness of the thermal control layers 118. The first thermal control layer 118a may expand and contract when undergoing phase changes. The placement of the bonding layer 112 in contact with the first thermal control layer 118a results in a lower amount of stress from a contraction or expansion of the first thermal control layer 118a within the integrated device.

In some embodiments, the second thermal control layer 118b and/or the third thermal control layer 118c are omitted. The second and third thermal control layers 118b, 118c are formed on opposite sides of the carrier substrate 110. In some embodiments, the second and third thermal control layers 118b, 118c are formed using one of ALD, CVD, PVD, or the like. In some embodiments, the second and third thermal control layers 118b, 118c are or comprise a same material as the first thermal control layer 118a. In other embodiments, the second and third thermal control layers 118b, 118c are or comprise a different PCM than the first thermal control layer 118a. In some embodiments, the second and third thermal control layers 118b, 118c have a second thickness between approximately 0.1 micrometers and 5 micrometers, between approximately 0.5 micrometers and 4 micrometers, between approximately 0.2 micrometers and 4.5 micrometers, or the like.

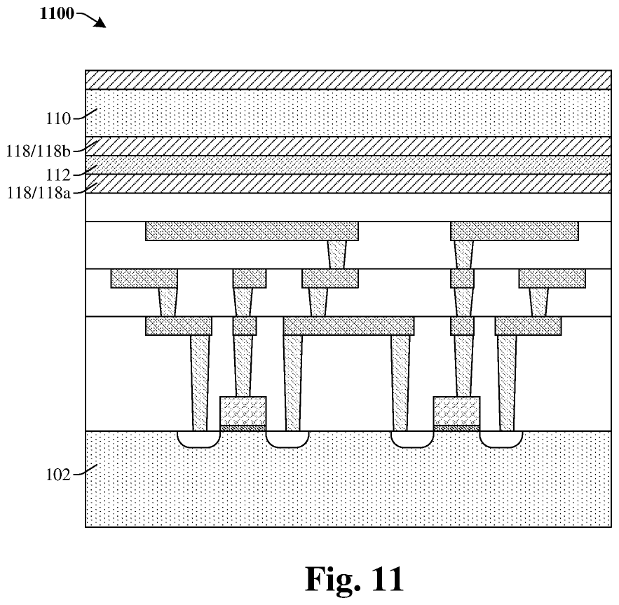

In some embodiments, a second high thermal conductivity layer and/or a third high thermal conductivity layer of the high thermal conductivity layers (see 502 of FIG. 5) are formed after or before the second thermal control layer 118b and the third thermal control layer 118c is formed. That is, the second high thermal conductivity layer may be formed after the second thermal control layer 118b, and the third high thermal conductivity layer may be formed before the third thermal control layer 118c. The method above results in the second high thermal conductivity layer being between the interconnect structure 106 and second thermal control layer 118b once the carrier substrate is bonded to the substrate (see 102 of FIG. 1) in the following steps (see FIG. 11). Further, the third high thermal conductivity layer will be between the interconnect structure 106 and the third thermal control layer 118c. The high thermal conductivity layers (see 502 of FIG. 5) distribute the heat generated in the active components across the thermal control layers 118, resulting in an increased heat transfer rate into the thermal control layers 118.

As shown in the cross-sectional view 1100 of FIG. 11, the carrier substrate 110 is bonded to the substrate 102 using the bonding layer 112. That is, the second thermal control layer 118b (or the carrier substrate 110, if the second thermal control layer 118b is omitted) is placed against the bonding layer 112. The bonding layer 112 is then hardened. In some embodiments, the bonding layer 112 may harden at room temperature. In other embodiments, the bonding layer 112 may be hardened using one or more of ultraviolet light, the application of pressure, or one or more heating cycles. The second thermal control layer 118b may expand and contract when undergoing phase changes. The placement of the bonding layer 112 in contact with the second thermal control layer 118b results in a lower amount of stress from a deformation or expansion of the second thermal control layer 118b within the integrated device, due to the relatively low stiffness of the bonding layer 112.

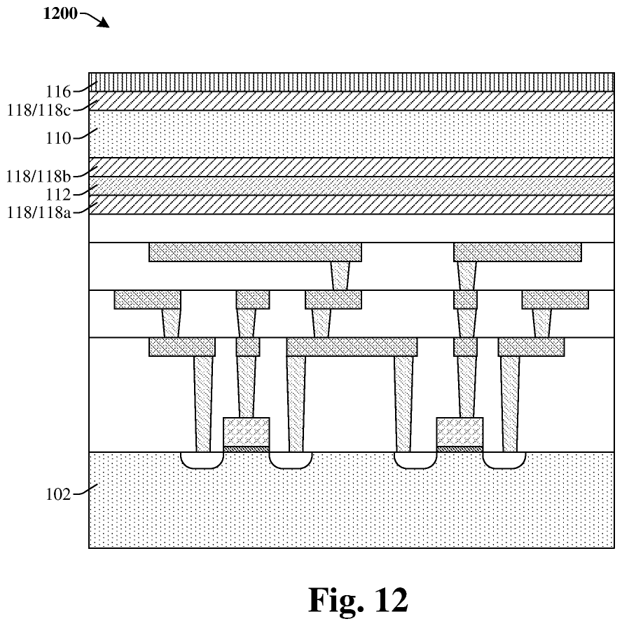

As shown in the cross-sectional view 1200 of FIG. 12, the TIM 116 is formed over the carrier substrate 110. In embodiments where the third thermal control layer 118c is not omitted, the TIM 116 is formed on the third thermal control layer 118c. The TIM 116 is or comprises a thermal interface material that conducts heat between the third thermal control layer 118c and a heat dissipating module (see 114 of FIG. 1) to be formed hereafter. In some embodiments, the TIM 116 is or comprises a thermal interface material such as thermal paste, thermal adhesive, or the like. The TIM 116 has a stiffness that is lower than a stiffness of the thermal control layers 118. The third thermal control layer 118c may expand and contract when undergoing phase changes. The placement of the TIM 116 in contact with the third thermal control layer 118c results in a lower amount of stress from a deformation or expansion of the third thermal control layer 118c within the integrated device.

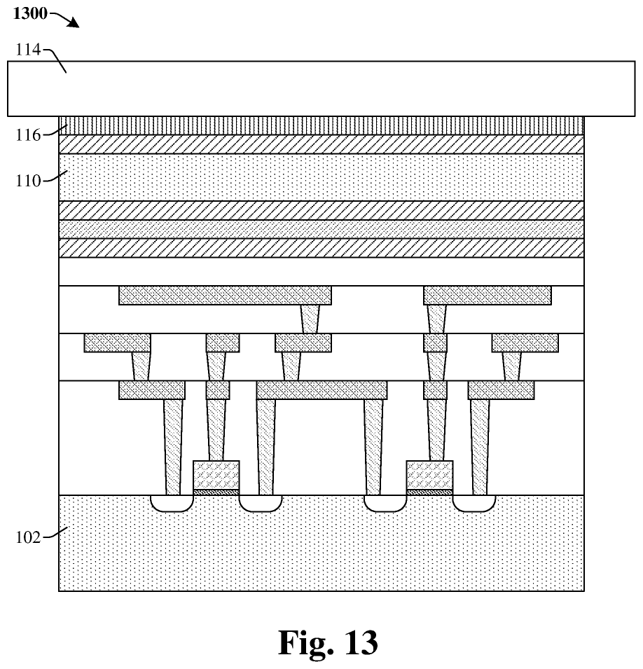

As shown in the cross-sectional view 1300 of FIG. 13, the heat dissipating module 114 is thermally coupled to the carrier substrate 110 by the TIM 116. The heat dissipating module 114 is or comprises a thermally conductive material, such as a metal, or the like. In some embodiments, the heat dissipating module 114 is coupled to one of the substrate 102, the second substrate (see 301 of FIG. 3), or the multilayer board (see 320 of FIG. 3) using an adhesive, soldering process, or the like.

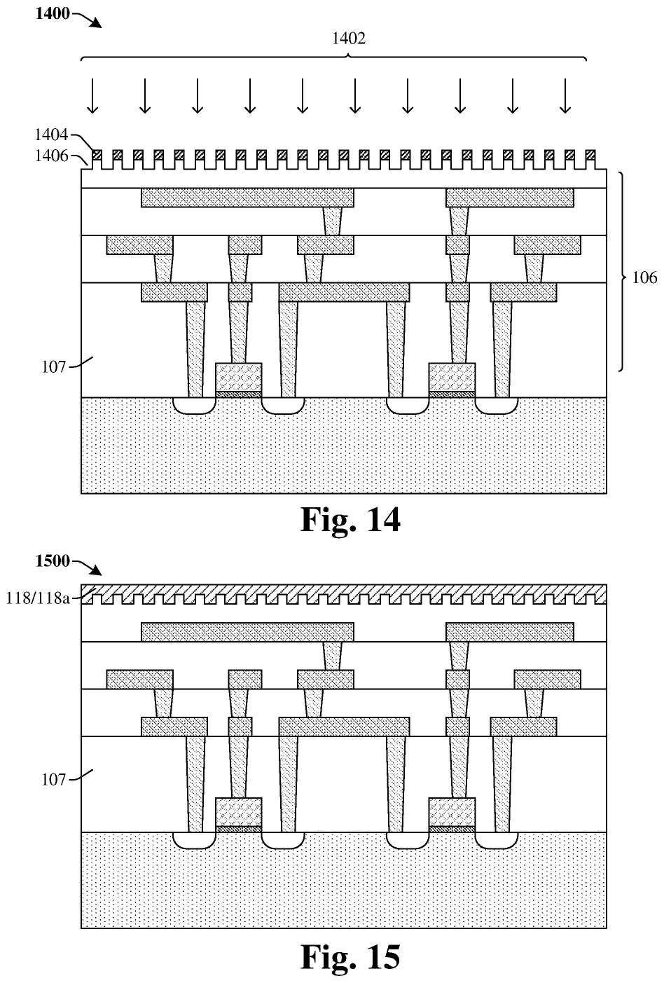

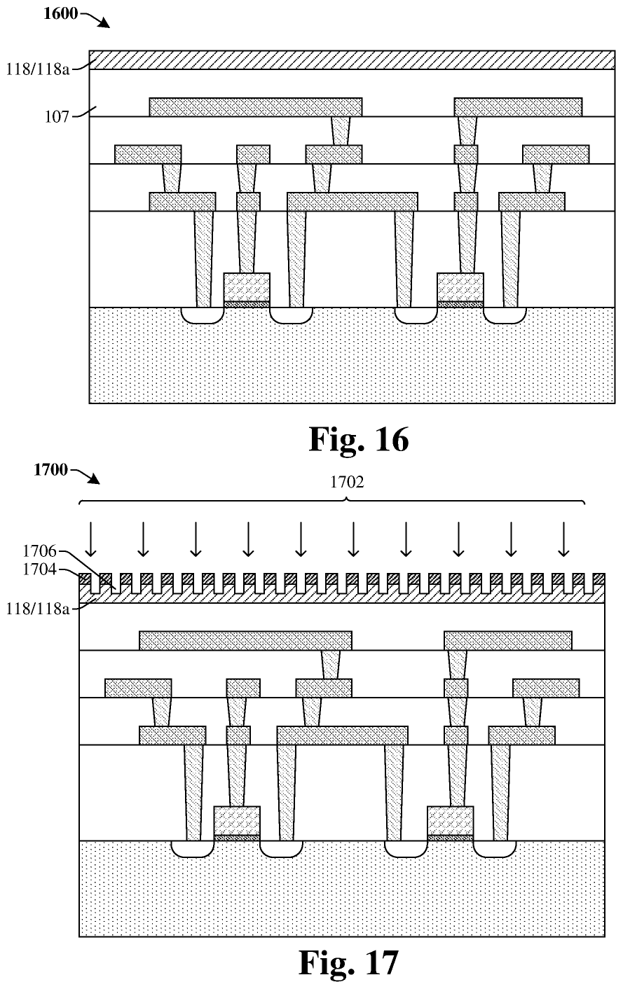

FIGS. 14-18 illustrate a series of cross-sectional views 1400-1800 of some embodiments of methods of forming one or more patterned thermal control layers disposed between the interconnect structure and an outer sidewall of the semiconductor package. FIGS. 14-15 illustrate a first method of forming a patterned thermal control layer and replaces FIG. 9 in some embodiments. FIGS. 16-19 illustrate a second method of forming a patterned thermal control layer and replaces FIG. 9 in some embodiments. The methods shown in FIGS. 14-15 and FIGS. 16-18 may also be used when forming the second thermal control layer (see 118b of FIG. 10) and/or the third thermal control layer (see 118c of FIG. 10), and different methods may be used for patterning the different thermal control layers 118.

As shown in the cross-sectional view 1400 of FIG. 14, after the interconnect structure 106 is formed, an etching process is performed on an uppermost layer of the interlayer dielectric 107 (also the underlying layer in relation to the first thermal control layer (see 118a of FIG. 1)). The etching process is performed by first forming and patterning a first masking layer 1404 on an upper surface of the interlayer dielectric. In some embodiments, the first masking layer 1404 is a photoresist and is patterned using photolithography. After the photoresist is patterned, a dry etching process 1402 is used to pattern the interlayer dielectric 107 according to the openings in the first masking layer 1404. The dry etching process 1402 forms a plurality of openings 1406 within the interlayer dielectric 107. After the dry etching process 1402, the first masking layer 1404 is removed.

As shown in the cross-sectional view 1500 of FIG. 15, the first thermal control layer 118a is formed within the plurality of openings (see 1406 of FIG. 14) in the underlying layer. The deposition process used to form the first thermal control layer 118a results in the first thermal control layer 118a conforming to and filling the plurality of openings (see 1406 of FIG. 14). Filling the plurality of openings results in the first thermal control layer 118a having a plurality of protrusions extending into the underlying layer. The first thermal control layer 118a therefore can have the increased surface area gained from patterning without directly etching the first thermal control layer 118a. The second thermal control layer (see 118b of FIG. 4) and the third thermal control layer (see 118c of FIG. 4) may also be formed using this technique by patterning opposite sides of the carrier substrate (see 110 of FIG. 4). Patterning the carrier substrate (see 110 of FIG. 1) results in the second thermal control layer (see 118b of FIG. 4) and the third thermal control layer (see 118c of FIG. 4) having a greater surface area on one side when formed (see FIG. 10), increasing the rate of heat transfer between the thermal control layers 118 and the carrier substrate (see 110 of FIG. 1).

As shown in the cross-sectional view 1600 of FIG. 16, the first thermal control layer 118a is formed on the interlayer dielectric 107, as in the steps described in relation to FIG. 9.

As shown in the cross-sectional view 1700 of FIG. 17, an etching process is performed on the first thermal control layer 118a. The etching process is performed by first forming and patterning a second masking layer 1704 on an upper surface of the interlayer dielectric. In some embodiments, the second masking layer 1704 is a photoresist and is patterned using photolithography. After the photoresist is patterned, a dry etching process 1702 is used to pattern the first thermal control layer 118a according to the openings in the second masking layer 1704. The dry etching process 1702 forms a plurality of openings 1706 within the first thermal control layer 118a, and leaving a plurality of protrusions extending from the first thermal control layer 118a. After the dry etching process 1702, the second masking layer 1704 is removed.

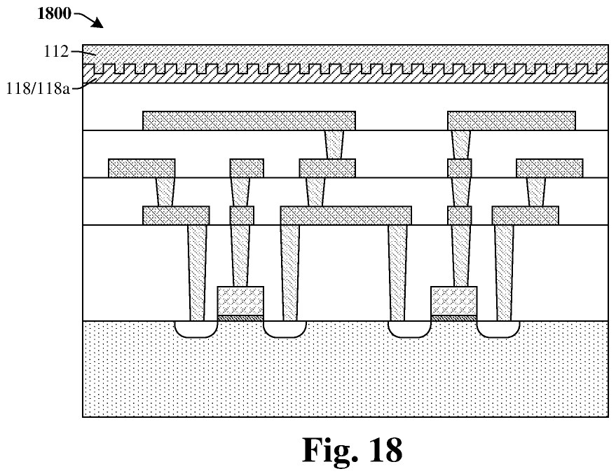

As shown in the cross-sectional view 1800 of FIG. 18, the bonding layer 112 is formed within the plurality of openings (see 1706 of FIG. 17) in the first thermal control layer 118a. The process used to form the bonding layer 112 results in the bonding layer 112 conforming to and filling the plurality of openings (see 1706 of FIG. 17). The first thermal control layer 118a therefore can have an increased surface area contacting the bonding layer 112, which may increase the bond strength and increase the rate of heat transfer between the first thermal control layer 118a and the bonding layer 112. The second thermal control layer (see 118b of FIG. 1) and the third thermal control layer (see 118c of FIG. 1) may also be formed using this technique by patterning them after the thermal control layers 118 are formed on the carrier substrate (see 110 of FIG. 1). Patterning the carrier substrate (see 110 of FIG. 1) results in the second thermal control layer (see 118b of FIG. 1) and the third thermal control layer (see 118c of FIG. 1) having a greater surface area on one side when formed (see FIG. 10), increasing the rate of heat transfer between the thermal control layers 118 and the carrier substrate (see 110 of FIG. 1).

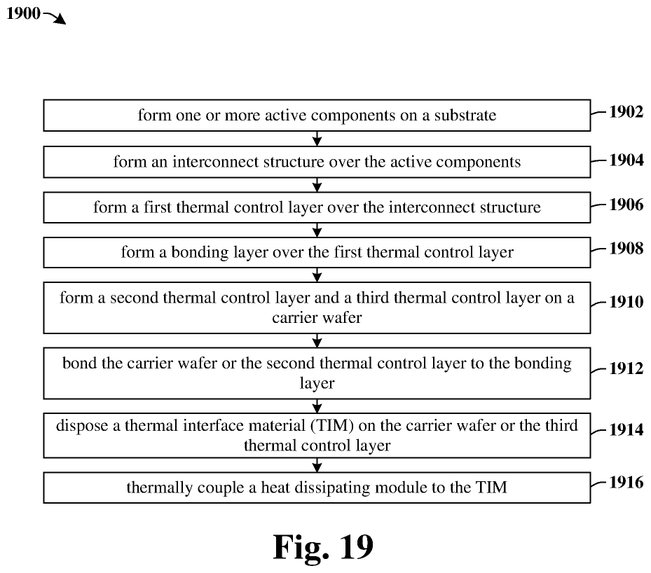

FIG. 19 illustrates a flowchart of some embodiments of a method of forming one or more patterned thermal control layers disposed between the interconnect structure and an outer sidewall of the semiconductor package. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At 1902, one or more active components are formed on a substrate. See, for example, FIG. 7.

At 1904, an interconnect structure is formed over the active components. See, for example, FIG. 8.

At 1906, a first thermal control layer is formed over the interconnect structure. See, for example, FIG. 9.

At 1908, a bonding layer is formed over the first thermal control layer. See, for example, FIG. 10.

At 1910, a second thermal control layer and a third thermal control layer are formed on a carrier substrate. See, for example, FIG. 10.

At 1912, the carrier substrate is bonded to the bonding layer. See, for example, FIG. 11.

At 1914, a thermal interface material (TIM) is disposed on the carrier substrate or the third thermal control layer. See, for example, FIG. 12.

At 1916, a heat dissipating module is thermally coupled to the TIM. See, for example, FIG. 13.

Some embodiments relate to an integrated device, including: a substrate having at least one active component; an interconnect structure disposed on the substrate; a bonding layer disposed over the interconnect structure; a carrier substrate disposed over the bonding structure; a heat dissipating module disposed over the carrier substrate; and a first thermal control layer disposed between the carrier substrate and the heat dissipating module, the bonding layer and the interconnect structure, or the carrier substrate and the bonding layer, where the first thermal control layer comprises a phase change material (PCM). In some embodiments, the integrated device further includes a high thermal conductivity layer on a first side of the first thermal control layer. In some embodiments, the integrated device further includes a second thermal control layer disposed between a different one of the carrier substrate and the heat dissipating module, the bonding layer and the interconnect structure, or the carrier substrate and the bonding layer than the first thermal control layer. In some embodiments, the integrated device further includes a third thermal control layer disposed between a different one of the carrier substrate and the heat dissipating module, the bonding layer and the interconnect structure, or the carrier substrate and the bonding layer than the first thermal control layer and the second thermal control layer. In some embodiments, the first thermal control layer comprises a solid-solid PCM (SS-PCM). In some embodiments, the SS-PCM is a shape memory alloy.

Other embodiments relate to an integrated device, including a substrate; an active component on the substrate; an interconnect structure coupled to the active component; a heat dissipating module disposed over the interconnect structure; and a first thermal control layer disposed between the interconnect structure and the heat dissipating module, wherein the first thermal control layer comprises a solid-solid phase change material (SS-PCM). In some embodiments, the integrated device further includes a thermal interface material on a first side of the first thermal control layer, wherein the thermal interface material has a first stiffness that is lower than a second stiffness of the first thermal control layer. In some embodiments, the first thermal control layer has a first side and a first plurality of protrusions extending from the first side. In some embodiments, the first thermal control layer further has a second side opposite the first side, and wherein the integrated device further comprises a high thermal conductivity layer covering the second side of the first thermal control layer. In some embodiments, the integrated device further includes a carrier substrate disposed between the first thermal control layer and the heat dissipating module; and a second thermal control layer disposed between the carrier substrate and the heat dissipating module. In some embodiments, the second thermal control layer comprises a second side and a second plurality of protrusions extending from the second side, wherein the first plurality of protrusions and the second plurality of protrusions extend into the carrier substrate. In some embodiments, the integrated device further includes a bonding layer between the interconnect structure and the first thermal control layer; and a third thermal control layer between the bonding layer and the interconnect structure, wherein the third thermal control layer comprises a third side and a third plurality of protrusions extending from the third side, and wherein the third plurality of protrusions extend towards the interconnect structure.

Yet other embodiments relate to a method of forming an integrated device, including providing a substrate; forming an active component on the substrate; forming an interconnect structure on the substrate; bonding a carrier substrate over the interconnect structure; forming a thermal interface material over the carrier substrate; positioning a heat dissipating module over the carrier substrate, wherein the thermal interface material thermally couples the carrier substrate to the heat dissipating module; and after forming the interconnect structure and before positioning the heat dissipating module, forming a first thermal control layer on the interconnect structure or the carrier substrate. In some embodiments, forming the first thermal control layer further includes forming the first thermal control layer on the carrier substrate before the carrier substrate is disposed on the interconnect structure; and forming a bonding layer on the interconnect structure, wherein after the carrier substrate is disposed over the interconnect structure, the carrier substrate and the first thermal control layer are mechanically coupled to the substrate by the bonding layer. In some embodiments, forming the first thermal control layer further includes: forming a second thermal control layer on the carrier substrate before the carrier substrate is disposed on the interconnect structure, wherein the second thermal control layer is spaced from the first thermal control layer by the carrier substrate; and bonding one of the first thermal control layer or the second thermal control layer to the bonding layer. In some embodiments, forming the first thermal control layer further includes: etching a plurality of grooves into one or more of the carrier substrate or the interconnect structure; and depositing a material of the first thermal control layer within the plurality of trenches, such that the first thermal control layer has a first plurality of protrusions extending into one of the carrier substrate or the interconnect structure. In some embodiments, the method further includes forming a bonding layer on the interconnect structure; and when the first thermal control layer is to be between the carrier substrate and the bonding layer, forming a first high thermal conductivity layer after forming the first thermal control layer, such that the first high thermal conductivity layer is between the first thermal control layer and the bonding layer. In some embodiments, forming the first thermal control layer further includes: depositing a material of the first thermal control layer onto the carrier substrate or the interconnect structure; and etching a plurality of trenches into the first thermal control layer, exposing a first plurality of protrusions of the first thermal control layer, such that the first thermal control layer has the first plurality of protrusions extending away from one of the carrier substrate or the interconnect structure. In some embodiments, when the first thermal control layer is to be formed on the interconnect structure, a first high thermal conductivity layer is formed before forming the first thermal control layer, such that the first high thermal conductivity layer is between the first thermal control layer and the interconnect structure.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated device, comprising:
a substrate comprising at least one active component;
an interconnect structure disposed on the substrate;
a bonding layer disposed over the interconnect structure;
a carrier substrate disposed over the interconnect structure;
a heat dissipating module disposed over the carrier substrate; and
a first thermal control layer disposed between the carrier substrate and the heat dissipating module, the bonding layer and the interconnect structure, or the carrier substrate and the bonding layer, the first thermal control layer comprising a phase change material (PCM).

2. The integrated device of claim 1, further comprising a high thermal conductivity layer on a first side of the first thermal control layer.

3. The integrated device of claim 1, further comprising a second thermal control layer disposed between a different one of the carrier substrate and the heat dissipating module, the bonding layer and the interconnect structure, or the carrier substrate and the bonding layer than the first thermal control layer.

4. The integrated device of claim 3, further comprising a third thermal control layer disposed between a different one of the carrier substrate and the heat dissipating module, the bonding layer and the interconnect structure, or the carrier substrate and the bonding layer than the first thermal control layer and the second thermal control layer.

5. The integrated device of claim 1, wherein the first thermal control layer comprises a solid-solid PCM (SS-PCM).

6. The integrated device of claim 5, wherein the SS-PCM comprises a shape memory alloy.

7. An integrated device, comprising:
a substrate;
an active component on the substrate;
an interconnect structure coupled to the active component;
a heat dissipating module disposed over the interconnect structure; and
a first thermal control layer disposed between the interconnect structure and the heat dissipating module, wherein the first thermal control layer comprises a phase change material (PCM).

8. The integrated device of claim 7, wherein the first thermal control layer comprises a solid-solid phase change material (SS-PCM).

9. The integrated device of claim 7, wherein the first thermal control layer comprises a first side and a first plurality of protrusions extending from the first side.

10. The integrated device of claim 9, wherein the first thermal control layer further comprises a second side opposite the first side, and wherein the integrated device further comprises a high thermal conductivity layer covering the second side of the first thermal control layer.

11. The integrated device of claim 9, further comprising:
a carrier substrate disposed between the first thermal control layer and the heat dissipating module; and
a second thermal control layer disposed between the carrier substrate and the heat dissipating module.

12. The integrated device of claim 11, wherein the second thermal control layer comprises a second side and a second plurality of protrusions extending from the second side, wherein the first plurality of protrusions and the second plurality of protrusions extend into the carrier substrate.

13. The integrated device of claim 12, further comprising:
a bonding layer between the interconnect structure and the first thermal control layer; and
a third thermal control layer between the bonding layer and the interconnect structure, wherein the third thermal control layer comprises a third side and a third plurality of protrusions extending from the third side, and wherein the third plurality of protrusions extend towards the interconnect structure.

14. A method of forming an integrated device, comprising:
providing a substrate;
forming an active component on the substrate;
forming an interconnect structure on the substrate;
bonding a carrier substrate over the interconnect structure;
forming a thermal interface material over the carrier substrate;
positioning a heat dissipating module over the carrier substrate, wherein the thermal interface material thermally couples the carrier substrate to the heat dissipating module; and
after forming the interconnect structure and before positioning the heat dissipating module, forming a first thermal control layer on the interconnect structure or the carrier substrate.

15. The method of claim 14, wherein forming the first thermal control layer further comprises:
forming the first thermal control layer on the carrier substrate before the carrier substrate is disposed on the interconnect structure; and
forming a bonding layer on the interconnect structure, wherein after the carrier substrate is disposed over the interconnect structure, the carrier substrate and the first thermal control layer are mechanically coupled to the substrate by the bonding layer.

16. The method of claim 15, wherein forming the first thermal control layer further comprises:
forming a second thermal control layer on the carrier substrate before the carrier substrate is disposed on the interconnect structure, wherein the second thermal control layer is spaced from the first thermal control layer by the carrier substrate; and
bonding one of the first thermal control layer or the second thermal control layer to the bonding layer.

17. The method of claim 14, wherein forming the first thermal control layer further comprises:
etching a plurality of grooves into one or more of the carrier substrate or the interconnect structure; and
depositing a material of the first thermal control layer within the plurality of grooves, such that the first thermal control layer has a first plurality of protrusions extending into one of the carrier substrate or the interconnect structure.

18. The method of claim 14, further comprising forming a bonding layer on the interconnect structure; and when the first thermal control layer is to be between the carrier substrate and the bonding layer, forming a first high thermal conductivity layer after forming the first thermal control layer, such that the first high thermal conductivity layer is between the first thermal control layer and the bonding layer.

19. The method of claim 14, wherein forming the first thermal control layer further comprises:
depositing a material of the first thermal control layer onto the carrier substrate or the interconnect structure; and
etching a plurality of trenches into the first thermal control layer, exposing a first plurality of protrusions of the first thermal control layer, such that the first thermal control layer has the first plurality of protrusions extending away from one of the carrier substrate or the interconnect structure.

20. The method of claim 14, wherein when the first thermal control layer is to be formed on the interconnect structure, forming a first high thermal conductivity layer before forming the first thermal control layer, such that the first high thermal conductivity layer is between the first thermal control layer and the interconnect structure.
